(19) United States
(12) Patent Application Publication
(10) Pub. No.: US 2026/0353593 A1
(43) Pub. Date: Nov. 5, 2026

(54) DEVICE FOR CONNECTING A PLURALITY OF APPARATUS HOUSINGS

(71) Applicant: Robert Bosch GmbH, Stuttgart (DE)

(72) Inventors: Reinhard Stangl, Wallersdorf (DE); Fabian Hoffmeister, Schoenau (DE); Werner Brauner, Salzweg (DE)

(21) Appl. No.: 19/488,165

(22) PCT Filed: May 17, 2024
(86) PCT No.: PCT/EP2024/063718

§ 371 Date: Nov. 26, 2025

(30) Foreign Application Priority Data
Jun. 7, 2023 (DE) 10 2023 205 338.1

(51) Int. Cl. H05K 7/18; F16M 13/02

(52) U.S. Cl. CPC H05K 7/18; F16M 13/02

(57) ABSTRACT

The invention relates to a device (100) for connecting a plurality of apparatus housings (200, 202) which, in a connected state, have pre-definable external dimensions (570) for accommodation in an equipment carrier (500), the device (100) comprising screw holes (120) adapted for an accommodation of screws for screwing the device (100) to a first side surface (210) of a first one (200) of the plurality of apparatus housings (200, 202), at least one connecting element (110) for connecting interaction with a second side surface (220) of a second one (202) of the plurality of apparatus housings (200, 202), the at least one connecting element (110) being respectively formed in the shape of a hook (110) which is adapted for engagement (390) in a recess (222) in the second side surface (220), and a fixing element (130) for fixing the connecting interaction with the second side surface (220). Furthermore, an arrangement of units is proposed that includes an equipment carrier and at least two apparatus housings accommodated in the equipment carrier and connected by means of such a device (100).

### BACKGROUND

The present invention relates to a device for connecting a plurality of apparatus housings for accommodation in an equipment carrier, as well as an arrangement of units comprising at least two apparatus housings connected to each other by means of such a device, which are accommodated in an equipment carrier.

From DE 10 2014 218 533 A1, an arrangement of units is known that comprises a 19-inch rack including at least one stacking device.

### SUMMARY

The basis of the invention is electrical and electronic devices installed in shelf-like equipment carriers, so-called racks. Such racks are frames into which the devices can be inserted and secured, for example, by way of screws. The racks are adapted, for example, to provide a pair of support rails for each device, onto which the device can be placed and inserted into the rack. Preferably, the device subsequently is fixed to the rack, for example by screwing it in place.

In particular, such racks or equipment carriers are standardized, so that the external dimensions of the apparatus housings to be accommodated in the equipment carrier are fixed. In particular, equipment carriers may have a standard width of 19 inches and then are referred to as 19-inch racks. The 19-inch rack, for example, may be composed of metal profiles, in particular steel profiles, and may have, for example, four vertically extending corner profiles and a plurality of horizontally extending support profiles.

The 19-inch rack is dimensioned in particular so that it can accommodate a front panel with a width of exactly 48.26 centimeters, i.e., 19 inches. In particular, the 19-inch rack can be formed to accommodate apparatus or apparatus housings with a standard width of 19 inches. The standardization is based on the EIA 310-D, IEC 60297, and/or DIN 41494 SC 48D regulations.

The invention proposes a device for connecting a plurality of apparatus housings as well as an arrangement of units comprising an equipment carrier and at least two apparatus housings connected to each other by means of such a device.

A device according to the invention for connecting a plurality of apparatus housings which, in a connected state have pre-definable external dimensions for accommodation in an equipment carrier, is adapted for attachment to a first side surface of a first one of the plurality of apparatus housings, comprises at least one connecting element for connecting interaction with a second side surface of a second one of the plurality of apparatus housings, and comprises a fixing element for fixing the connecting interaction with the second side surface. Connecting the apparatus housings via the respective side surfaces saves installation space compared to connecting the apparatus housings via the respective bottom sides, as no recess is required in the respective bottom side of the apparatus housings. This allows to fully exhaust the height available within the pre-definable external dimensions within the respective apparatus housing. In addition, less consideration needs to be given to components installed in the housing, in particular circuit carriers, such as printed circuit boards, which are usually mounted on the bottom side of the housing, when attaching the device to the respective apparatus housing.

The at least one connecting element is respectively formed in the shape of a hook that is adapted for engagement in a recess in the second side surface. This enables particularly easy assembly, especially by means of a sliding movement for hooking in, and requires virtually no installation space within the second apparatus housing.

The device comprises screw holes that are adapted for an accommodation of screws for screwing the device to the first side surface of the first one of the plurality of apparatus housings.

In at least one embodiment, the at least one connecting element comprises at least two, three, or four connecting elements. This ensures a particularly stable connection, especially one that is resistant to twisting. In at least one embodiment, all connecting elements can be identical in shape, which facilitates both manufacture and use.

In at least one embodiment, the fixing element is designed to connect the device to a surface of the second apparatus housing that is not in the same plane as the second side surface. Such a design facilitates assembly and keeps the outer shape of the apparatus housings connected with each other compact.

In at least one embodiment, the fixing element is provided in the form of a lug formed to be screwed to the second apparatus housing. This is a cost-effective, easy-to-implement, and secure solution. Preferably, the lug is designed at right angles to the rest of the flat metal sheet of the device. In particular, the lug has a hole for screwing the lug to the second apparatus housing. Preferably, the lug is designed so as to be arranged in a recess in the bottom side of the second apparatus housing and screwed to the bottom side of the second apparatus housing by means of a fixing screw.

In at least one embodiment, the device consists predominantly of a metal sheet with a thickness of less than 10 mm, 5 mm, 3 mm, 2 mm, 1 mm, or 0.5 mm. This provides a particularly cost-effective, stable, and space-saving solution. Punching processes or water jet or laser cutting, for example, can be used for manufacturing such a design.

In at least one embodiment, the device is dimensioned such that, when attached to the first side of the first apparatus housing, it does not protrude beyond any edge of the first side surface. This makes it particularly easy to install apparatus housings connected by means of the device in a corresponding equipment carrier.

In at least one embodiment, the screw holes for attachment to the first side surface coincide with screw holes provided in the first side surface, so that the device can be attached to the first side surface by removing screws from the screw holes provided in the first side surface and attaching or screwing the device to the first side surface using the removed screws. Typically, components of the apparatus housing (e.g., bottom, front and rear side, top side, and both side surfaces) are fixed in place with screws anyway. In this embodiment, in particular a screw connection of the side surface, which is used in particular to fix the side surface in place, thus can be used at the same time for attachment of the device, so that no additional screws (and no additional counter threads) are required for this purpose.

In at least one embodiment, the device has at least one recess that is adapted to align with one or more ventilation opening(s) in the first and/or second side surface of the respective apparatus housing when assembled. This allows air to circulate between the apparatus housings connected with each other, which can be beneficial for temperature management of devices installed in the housings.

Furthermore, the invention comprises an apparatus housing arrangement comprising at least two apparatus housings, preferably exactly two apparatus housings, which are connected to each other by means of at least the device described above.

An arrangement of units according to the invention comprises an equipment carrier adapted for accommodation of apparatus housings with pre-definable external dimensions and at least two apparatus housings which are connected to each other by means of at least one device as described above, wherein the apparatus housings connected to each other by means of the at least one device, jointly having the pre-definable external dimensions and being accommodated in the equipment carrier. The arrangement of units therefore benefits from the advantages of the device in a corresponding manner. In particular, the device makes it possible to also make use of smaller apparatus housings in an equipment carrier laid out for larger apparatus housings without additional adaptation.

Further advantages and embodiments of the invention are apparent from the description and the accompanying figures.

The invention is schematically illustrated in the drawing by means of an embodiment and is described below with reference to the figures.

### BRIEF DESCRIPTION OF THE DRAWINGS

FIG. 1 shows a side view of a device according to the invention.

FIG. 2 shows a perspective view of the device shown in FIG. 1 being mounted to a first apparatus housing.

FIG. 3 shows a perspective view of the connection of a second apparatus housing to the first apparatus housing equipped with the device shown in FIG. 2.

FIG. 4 shows in a perspective view of a bottom side of the apparatus housings connected to each other as shown in FIG. 3, the fixation of the apparatus housings connected to each other.

FIG. 5 schematically shows an arrangement with an equipment carrier in which apparatus housings connected to each other by a device according to the invention, are accommodated, in accordance with an embodiment of the present invention.

### DETAILED DESCRIPTION

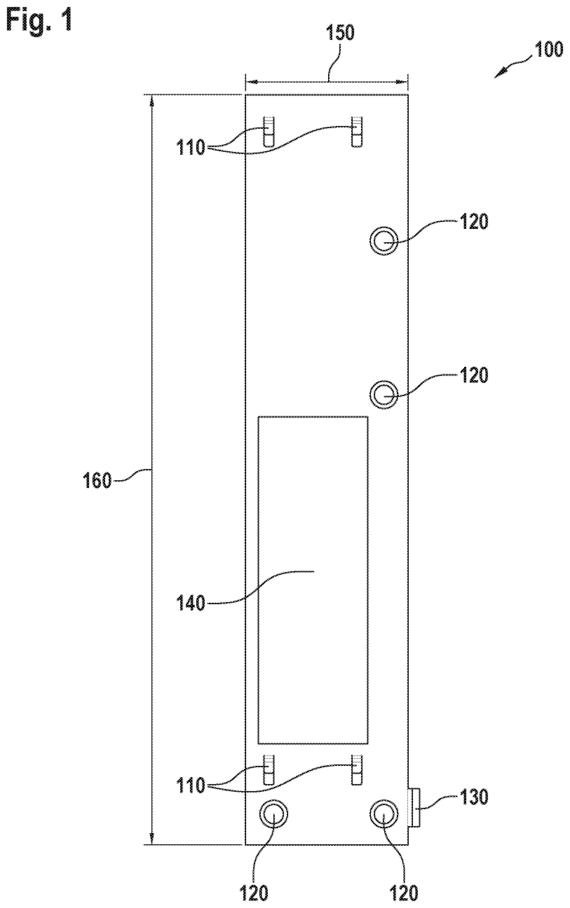

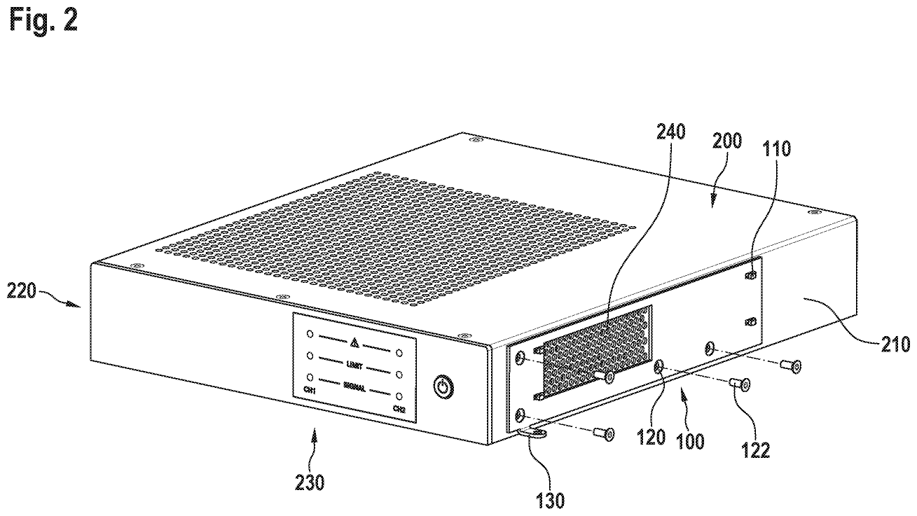

FIG. 1 shows a side view of an embodiment of the device according to the invention, designated as a whole by 100. FIG. 2 shows the mounting of the device to a first apparatus housing designated as a whole by 200.

In the example shown here, device 100 is manufactured in one piece from sheet steel (e.g., by punching, water jet cutting, laser cutting, machining processes, or combinations thereof) and comprises four connecting elements 110, which are designed here in the form of hooks of identical shape (here, for example, formed by bending).

The device 100 further comprises screw holes 120 (four in this case), a fixing element 130 (in this case in the form of a lug that protrudes essentially perpendicularly from the drawing plane of FIG. 1) and a recess 140. In the example shown here, the screw holes 120 are countersunk, so that when corresponding countersunk bolts 122 are used for attachment of the device 100 to the first apparatus housing 200, the screw heads are essentially flush with a surface of the device 100.

The recess 140 is arranged so that, during assembly, it aligns with ventilation openings 240 in a first side surface 210 of the first apparatus housing 200, so that these ventilation openings 240 remain at least partially accessible even after the device has been assembled.

As can be seen in FIG. 2, the length 160 and width 150 of the device 100 are dimensioned such that the device 100 does not protrude beyond any edge of the first side surface 210 of the first apparatus housing 200. In other words, the length 160 of the device 100 is smaller than (or at most equal to) a depth of the first apparatus housing 200, and the width 150 of the device 100 is smaller than (or at most equal to) a height of the first apparatus housing 200.

The screw holes 120 of the device 100 are arranged so that they match screw holes provided in the first side surface 210 of the first apparatus housing so that, for mounting the device 100 to the first side surface 210, the screws 122 can be removed from the screw holes provided in the first side surface 210 and used for mounting the device 100. It is understood that in the case of initial assembly of the first apparatus housing 200, the screws 122 do not need to be removed first, as they have not yet been installed in such a case.

From FIG. 2 it is apparent that the device 100 is mounted so that the hooks 110 and the lug 130 point away from the first apparatus housing 200, with the lug 130 being arranged essentially in the same plane as a bottom side or floor space 230 of the first apparatus housing.

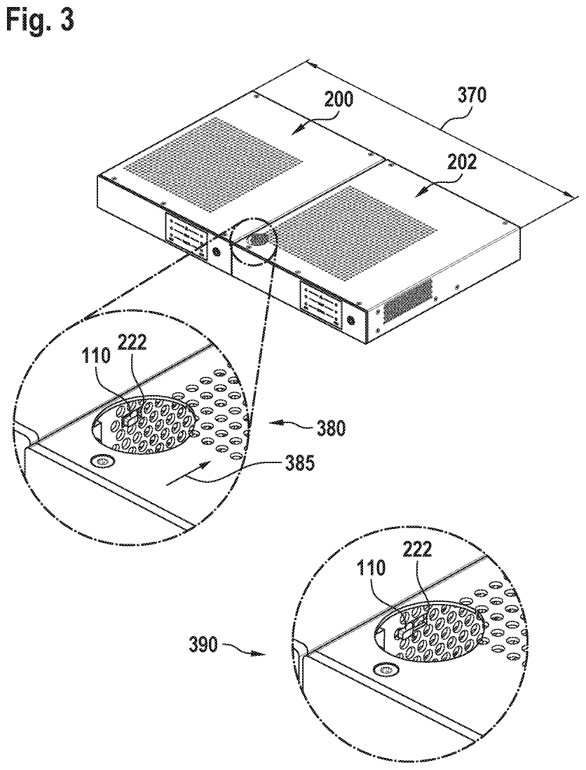

FIG. 3 shows a perspective view of the connection of a second apparatus housing 202 to the first apparatus housing 200 provided with the device 100 according to FIG. 2.

In this case, the second apparatus housing 202, which in the example shown has an outer shape identical to that of the first apparatus housing 200, is attached to the device 100 with a second side surface 220 opposite the first side surface 210 in such a way that each hook 110 protrudes through a corresponding recess 222 in the second side surface. This state is designated by 380 in FIG. 3.

By shifting the first 200 and second 202 apparatus housings parallel to each other (indicated by arrow 385), the hooks 110 engage with the respective recess 222 so that the two apparatus housings 200, 202 can no longer move away from each other. This situation in which the hook 110 engages with the respective recess 222, is designated by 390 in FIG. 3.

In such a connected state, the first 200 and second 202 apparatus housings connected to one another have a common width 370 that corresponds to the standard width of an equipment carrier, for example, a standardized insertion width of a 19-inch rack. For example, the common width 370 may be 450 mm (17.72 inches), which corresponds to the standard insertion width of a 19-inch rack.

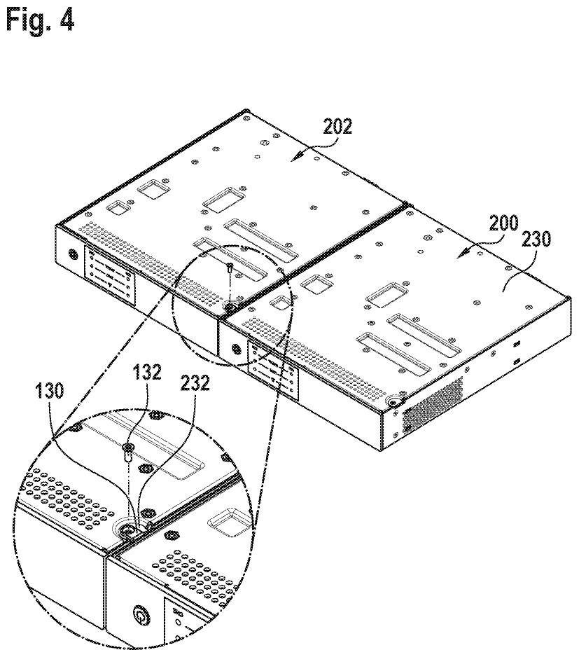

FIG. 4 shows the fixation of the apparatus housings 200, 202 connected to each other in a perspective view of a bottom side 230 of the apparatus housings 200, 202 connected according to FIG. 3.

As can be seen in FIG. 4, the lug 130 (fixing element) protrudes into a recess 232 in the bottom side 230 of the second apparatus housing 202 and can be screwed therein using a fixing screw 132. This immobilizes the second apparatus housing 202 relative to the device 100 and thus also relative to the first apparatus housing 200, in particular in the direction of the parallel shift 385 shown in FIG. 3.

In summary, merely a single additional screw thus is required for secure connection of the two apparatus housings 200, 202, which restricts the installation space inside the apparatus housings 200, 202 only minimally.

It is understood that the invention can also be used to connect more than two apparatus housings. However, it is particularly advantageous to combine apparatus housings with each other that, in a connected state, together have the aforementioned standard width 370. It is not necessary for the apparatus housings respectively connected to each other to be of equal width.

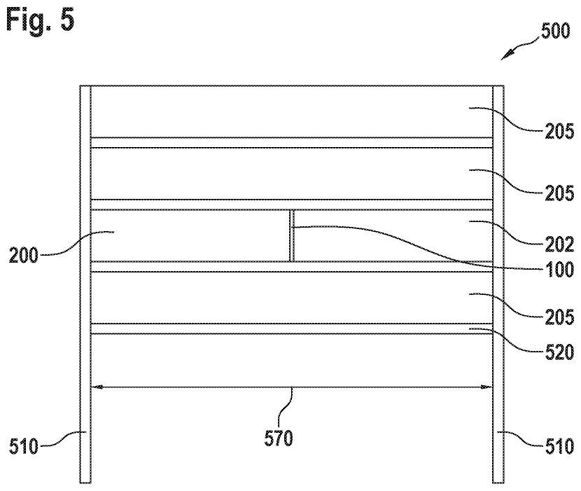

FIG. 5 schematically shows an arrangement with an equipment carrier according to one embodiment of the present invention, the equipment carrier in total being designated by 500.

In the example shown, the equipment carrier 500 has vertically extending corner profiles 510 and horizontally extending support profiles 520. In the example shown here, the equipment carrier 500 contains three apparatus housings 205, the width of which corresponds to accommodation width 570 of the equipment carrier, for example 19 inches. Furthermore, the equipment carrier 500 accommodates a combination of a first 200 and a second 202 apparatus housing, which housings are connected to each other by means of the device 100, the width of the combination likewise corresponding to accommodation width 570 of equipment carrier 500.

It is understood that devices can be installed in the apparatus housings 200, 202, 205. For example, the apparatus housings can be used for accommodation of electronic devices such as computers, in particular server assemblies or servers, amplifiers, e.g., power amplifiers, or the like. The device 100 is mounted advantageously after the respective device has been mounted in apparatus housings 200, 202. Preferably, the device installed in apparatus housings 200, 202, 205 is an audio device, in particular an audio amplifier and/or an audio mixer.

1. A device (100) for connecting a plurality of apparatus housings (200, 202) to each other which, in a connected state, have pre-definable external dimensions (570) for accommodation in an equipment carrier (500),
wherein the device (100) comprises:
screw holes (120) for receiving screws for screwing the device (100) to a first side surface (210) of a first (200) of the plurality of apparatus housings (200, 202),
at least one connecting element (110) for connecting interaction with a second side surface (220) of a second one (202) of the plurality of apparatus housings (200, 202), the at least one connecting element (110) respectively being formed in a shape of a hook (110) that is configured for engagement (390) in a recess (222) in the second side surface (220), and
a fixing element (130) for fixing the connecting interaction with the second side surface (220).

2. The device (100) according to claim 1, wherein the at least one connecting element (110) comprises at least two, three, or four connecting elements (110).

3. The device (100) according to claim 2, wherein all connecting elements (110) are identical in shape.

4. The device (100) according to claim 1, wherein the fixing element (130) is configured for connecting the device (100) to a surface (230) of the second apparatus housing (202) that is not in a same plane as the second side surface (220).

5. The device (100) according to claim 1, wherein the fixing element (130) is in a form of a lug (130) which is configured for screw connection (132) with the second apparatus housing (202).

6. The device (100) according to claim 1, which is configured predominantly of a metal sheet with a thickness of less than 10 mm.

7. The device (100) according to claim 1, wherein the device (100) is dimensioned (150, 160) such that, when attached to the first side (210) of the first apparatus housing (200), it does not protrude beyond any edge of the first side surface (210).

8. The device (100) according to claim 1, wherein the screw holes (120) coincide with screw holes provided in the first side surface (210) so that the device (100) can be attached to the first side surface (210) by removing screws (122) from the screw holes provided in the first side surface (210) and attaching the device (100) to the first side surface (210) using the removed screws (122).

9. The device (100) according to claim 1, with at least one recess (140) which is adapted to align, in an assembled state, with one or more ventilation openings (240) in the first (210) and/or second (220) side surface of the respective apparatus housing (200, 202).

10. An arrangement of housing units comprising at least two apparatus housings (200, 202) which are connected to each other by at least one device (100) according to claim 1.

11. The arrangement of units comprising an equipment carrier (500) which is adapted for accommodation of apparatus housings (205) with pre-definable external dimensions (570), and
at least two apparatus housings (200, 202) which are connected to each other by at least one device (100) according to claim 1,
wherein the apparatus housings (200, 202) connected by the at least one device (100) jointly have the pre-definable external dimensions (570) and are accommodated in the equipment carrier (500).

12. The device (100) according to claim 6, wherein the metal sheet has a thickness of less than 5 mm.

13. The device (100) according to claim 12, wherein the metal sheet has a thickness of less than 3 mm.

14. The device (100) according to claim 13, wherein the metal sheet has a thickness of less than 2 mm.

15. The device (100) according to claim 14, wherein the metal sheet has a thickness of less than 1 mm.

16. The device (100) according to claim 15, wherein the metal sheet has a thickness of less than 0.5 mm.
